(19) United States
(12) Patent Application Publication
(10) Pub. No.: US 2008/0264342 A1
(43) Pub. Date: Oct. 30, 2008

(54) DEPOSITION APPARATUS

(75) Inventors: Akira Saito, Tokyo (JP); Naoki Uetake, Kanagawa (JP)

Correspondence Address: SONNENSCHEIN NATH & ROSENTHAL LLP, P.O. BOX 061080, WACKER DRIVE STATION, SEARS TOWER, CHICAGO, IL, 60606-1080, US

(73) Assignee: SONY CORPORATION, Tokyo (JP)

(21) Appl. No.: 12/108,674

(22) Filed: Apr. 24, 2008

(30) Foreign Application Priority Data
Apr. 26, 2007 (JP) 2007-116370

(51) Int. Cl. C23C 16/44

(52) U.S. Cl. 118/726

(57) ABSTRACT

A deposition apparatus is provided that includes a plurality of line-type evaporation sources provided to be arranged in a predetermined direction; and a movement and support device which supports the plurality of line-type evaporation sources so as to be individually movable in the arrangement direction and/or longitudinal direction of the evaporation sources.

### CROSS REFERENCES TO RELATED APPLICATIONS

The present invention contains subject matter related to Japanese Patent Application JP 2007-116370 filed in the Japan Patent Office on Apr. 26, 2007, the entire contents of which being incorporated herein by reference.

### BACKGROUND OF THE INVENTION

1. Field of the Invention

The present invention relates generally to deposition apparatuses used to form a thin film on a substrate, and more particularly to a deposition apparatus provided with line-type evaporation sources.

2. Description of the Related Art

Among flat display devices, ones using organic electroluminescent elements (organic EL elements: EL stands for electroluminescence) have drawn attention in the recent years. The display devices using organic electroluminescent elements (hereinafter, referred also to as “organic EL displays”) have advantages such as a wide view angle, low power consumption and the like because they are light-emitting displays, that is, they do not need a backlight.

Organic electroluminescent elements used in an organic EL display are generally configured to put an organic layer made of an organic material between upper and lower electrodes (an anode and a cathode). Positive voltage and negative voltage are applied to the anode and to the cathode, respectively, to inject holes and electrons to the organic layer from the anode and from the cathode, respectively. Thus, a hole and an electron are recombined with each other in the organic layer to emit light.

The organic layer of the organic electroluminescent element is of a multilayer structure including a hole-injecting layer, a hole transport layer, an emission layer and a charge-injection layer. An organic material forming each of the layers cannot use a wet process because of low water resistance. For this reason, to form the organic layer, each of the layers is sequentially formed on an element substrate (usually a glass substrate) of an organic electroluminescent element to provide a desired multilayer structure. In addition, to deal with colorization, organic materials of three kinds corresponding to R (red), G (green) and B (blue) color-components are deposited at respective different pixel positions by a vacuum deposition method using a vacuum thin-film forming technique, thereby forming an organic layer.

A vacuum deposition apparatus is used to form an organic layer. The increased floor area of a vacuum chamber leads to a soaring cost of the vacuum deposition apparatus and to an increased installation area of the apparatus, thereby increasing installation cost. Thus, negative elements are increased in view of costs. In addition, the increased volume of the vacuum chamber increases the time necessary for vacuuming, thus tending to lower productive efficiency.

To deal with enlargement of a substrate on which films are to be formed by vacuum deposition (hereinafter referred to as “the to-be-processed substrate”) and with the multi-stratification of an organic layer, line-type lengthy evaporation sources have been employed in recent years. In addition, a deposition apparatus is proposed in which a plurality of such evaporation sources are provided to be arranged in a vacuum chamber (see Japanese Patent Laid-Open No. 2003-157973).

### SUMMARY OF THE INVENTION

If a plurality of line-type evaporation sources are provided to be arranged as described above, the interval between the adjacent evaporation sources is reduced to make the floor area of the vacuum chamber and the installation area small. However, the reduced interval between the adjacent evaporation sources and the reduced floor area of the vacuum chamber will reduce a working space where the deposition apparatus is maintained in the vacuum chamber. Examples of the maintenance work for the deposition apparatus include filling work of an evaporation material into evaporation sources; replacement work of a film-thickness sensor (which uses e.g. a crystal oscillator); and cleaning work for an adhesion prevention plate adapted to prevent the evaporation material from adhering to a portion that does not need the evaporation material and for a restrictive plate adapted to restrict a deposition range.

It is desirable to provide a deposition apparatus that can provide satisfactory maintenance performance without setting the wide installation interval between line-type evaporation sources.

According to an embodiment of the present invention, there is provided a deposition apparatus including: a plurality of line-type evaporation sources provided to be arranged in a predetermined direction; and movement and support means for supporting the plurality of line-type evaporation sources so as to be individually movable in the arrangement direction and/or longitudinal direction of the evaporation sources.

In the deposition apparatus according to the embodiment of the invention, a space used for maintenance can be broadened in a vacuum chamber by moving the evaporation sources in any of the arrangement direction and longitudinal direction thereof.

According to the invention, the wide space used for maintenance can be ensured by moving each of the evaporation sources as necessary during the maintenance without setting the wide installation interval between the evaporation sources in the vacuum chamber.

### BRIEF DESCRIPTION OF THE DRAWINGS

FIG. 1 is a schematic view illustrating an explanatory configuration of a deposition apparatus according to an embodiment of the present invention;

FIGS. 2A and 2B are schematic views illustrating a major portion of the deposition apparatus according to the embodiment of the present invention;

FIG. 3 illustrates movement of line-type evaporation sources by way of example;

FIG. 4 illustrates movement of the line-type evaporation source by way of another example;

FIG. 5 illustrates a configuration of a typical evaporation source by way of example;

FIGS. 6A and 6B illustrate a first configurational example of the line-type evaporation source;

FIGS. 7A and 7B illustrate a second configurational example of the line-type evaporation source;

FIGS. 8A and 8B illustrate a third configurational example of the line-type evaporation source;

FIGS. 9A and 9B illustrate a fourth configurational example of the line-type evaporation source;

FIG. 10 illustrates a configurational example of a crucible unit; and

FIGS. 11A and 11B illustrate a fifth configurational example of the line-type evaporation source.

### DETAILED DESCRIPTION OF THE PREFERRED EMBODIMENTS

Embodiments of the present invention will hereinafter be described in detail with reference to the drawings.

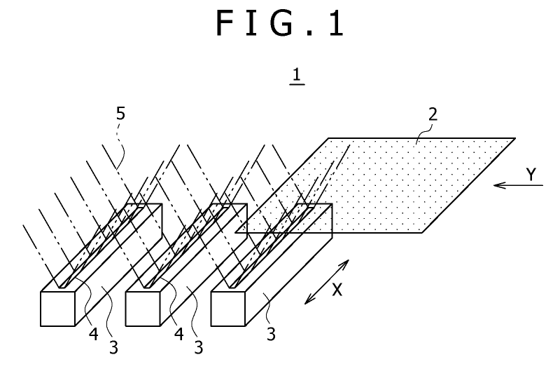

FIG. 1 is a schematic view illustrating an explanatory configuration of a deposition apparatus according to an embodiment of the present invention. A deposition apparatus 1 illustrated in the figure is used to deposit an organic layer on a to-be-processed substrate 2 made of e.g. a glass substrate in manufacturing a display device using e.g. organic electroluminescent elements.

The deposition apparatus 1 is equipped with a vacuum chamber not shown. The vacuum chamber of the deposition apparatus 1 is internally provided with a conveying device (not shown) adapted to convey a to-be-processed substrate 2 and with a plurality of line-type evaporation sources 3. The conveying device relatively moves the to-be-processed substrate 2 and the line-type evaporation sources 3 in a Y-direction by moving the to-be-processed substrate 2 in the Y-direction (horizontal movement) while horizontally supporting the to-be-processed substrate 2 at a position opposed to the line-type evaporation sources 3.

The line-type evaporation sources 3 are provided to be arranged in the Y-direction at given intervals. The intervals of the line-type evaporation sources 3 installed in the Y-direction are applied to the formation of films on the to-be-processed substrate 2 in a vacuum. The line-type evaporation sources 3 are each formed lengthy. The longitudinal direction (line-direction) of each evaporation source is arranged parallel to the X-direction perpendicular to the Y-direction. The line-type evaporation sources 3 are each provided with an ejection port 4 for evaporation material. The ejection port 4 is formed in a slit-like shape extending along the longitudinal direction of the line-type evaporation source 3 at a position opposed to the to-be-processed substrate 2.

Incidentally, the number of installed line-type evaporation sources 3 is not limited to three and may be two or four or more. In addition, the ejection port 4 of the line-type evaporation source 3 is not limited to the slit-like shape. For example, small ejection ports shaped in circle as viewed from above may be arranged along the longitudinal direction of the line-type evaporation source 3.

The deposition apparatus 1 configured as described above allows the conveying device not shown to move the to-be-processed substrate 2 in the Y-direction while causing the evaporation material 5 such as an organic material to eject from the respective ejection ports 4 of the line-type evaporation sources 3. Thus, the deposition films such as organic films are deposited on the to-be-processed substrate 2. In this case, organic materials different in type from each other may be each ejected from a corresponding one of three line-type evaporation sources 3 arranged in the Y-direction for example to deposit the organic films of three layers on the to-be-processed substrate.

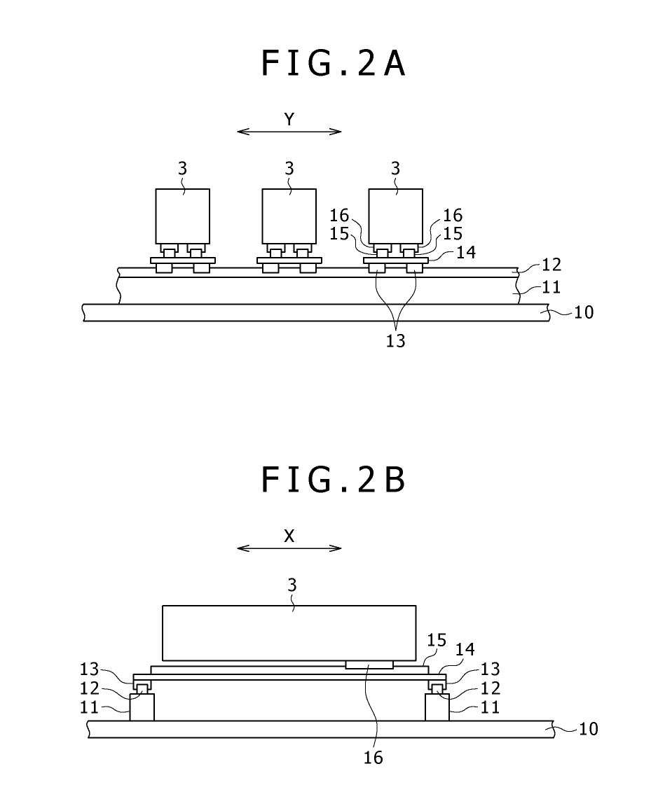

FIGS. 2A and 2B are schematic views illustrating a major portion of the deposition apparatus according to the embodiment of the present invention, as viewed from the X-direction and from the Y-direction, respectively. In FIGS. 2A and 2B, a pair of support members 11 are provided so as to be secured to a bottom wall 10 of the vacuum chamber of the deposition apparatus. The support members 11 are each formed like a rectangular column elongate in the Y-direction and are spaced at a given distance apart from each other in the X-direction.

Rail members 12 are each attached to a corresponding one of the respective upper surfaces of the support members 11 fixedly thereto. The rail members 12 are each attached parallel to the Y-direction. A plurality of slide members 13 are mounted on each of the rail members 12. The slide members 13 are provided to be movable along the rail members 12 in the Y-direction. Four slide members 13 are provided for each of the line-type evaporation sources 3: two of them are mounted on one of the rail members 12 and the other two are mounted on the other.

The four slide members 13 for each of the line-type evaporation sources 3 are attached to the lower surface of a common base member 14. This base member 14 has a lengthy flat plate structure and is disposed parallel to the X-direction so as to be spanned between the pair of support members 11.

A pair of rail members 15 are fixedly attached to the upper surface of the base member 14. The rail members 15 are each attached parallel to the X-direction. A plurality of slide members 16 are each mounted on a corresponding one of the rail members 15. The slide members 16 are provided to be movable along the rail members 15 in the X-direction. Two slide members 16 are provided for each of the line-type evaporation sources 3: one of them is mounted on one of the rail members 15 and the other is mounted on the other.

A common line-type evaporation source 3 is mounted on the upper surfaces of the two slide members 16 corresponding to one line-type evaporation source 3. The slide members 16 are each attached at a position close to one side of the line-type evaporation source 3 in the longitudinal direction (the X-direction). The reason why the slide member 16 is disposed close to one side of the line-type evaporation source 3 is that the long movable distance of the line-type evaporation source 3 is intended to be ensured when the line-type evaporation source 3 is moved in the X-direction.

In the deposition apparatus 1 according to the embodiment of the present invention, the support members 11, the rail members 12, the slide members 13, the base member 14, the rail members 15 and the slide members 16 mentioned above constitute “movement and support means” or the movement and support device. Among them, the rail members 12 and the slide members 13 serve as a slide mechanism adapted to move the line-type evaporation source 3 in the Y-direction and the rail members 15 and the slide members 16 serve as slide mechanism adapted to move the line-type evaporation source 3 in the X-direction.

With the movement and support device configured as described above, for each line-type evaporation source 3, moving the four slide members 13 along the pair of rail members 12 and moving the two slide members 16 along the pair of rail members 15 can move each of the three line-type evaporation sources 3 in each of the X- and Y-directions.

That is to say, for the movement of the X-direction, of the three line-type evaporation sources 3, one optional line-type evaporation source 3 can be moved, also two optional line-type evaporation sources 3 can be moved, and all the line-type evaporation sources 3 can be moved. In addition, two optional line-type evaporation sources 3 can be moved sequentially or simultaneously (integrally). All the three line-type evaporation sources 3 can be moved sequentially or simultaneously (integrally). These points hold true for the movement in the Y-direction.

The system of moving the line-type evaporation sources 3 may be of an automatic type using a motor or the like as a drive source or of a manual type using human-power. If the automatic type is employed in particular, the line-type evaporation sources 3 can each be moved to a desired position by simple operation (e.g. button operation). This makes it possible to be quickly shifted to maintenance work. If the manual type is employed, it is not necessary to incorporate a drive source such as a motor or the like and a control circuit such as a motor driver or the like. This makes it possible to keep the cost of the deposition apparatus 1 low.

In the manufacture of the display device using organic electroluminescent elements, when an evaporation material is actually deposited on a to-be-processed substrate 2, it is necessary to accurately locate the line-type evaporation source 3 at a predetermined position in the X- and Y-directions.

To meet the necessity, with regard to the X-direction, although not shown, first and second securing members secured to the base member 14 and to the slide member 16 or to the line-type evaporation source 3, respectively, are provided with respective positioning holes. In addition, a common positioning pin is inserted to the positioning holes to position the line-type evaporation source 3.

With regard to the Y-direction, third and fourth securing members secured to the base member 14 and to the support member 11, respectively, are provided with respective positioning holes. In addition, a common positioning pin is inserted into the positioning holes to position the line-type evaporation source 3.

With the employment of such a movement and support device, when maintenance work is carried out by returning the inside of the vacuum chamber to the atmosphere pressure, the line-type evaporation source 3 can freely be moved by pulling out the positioning pins.

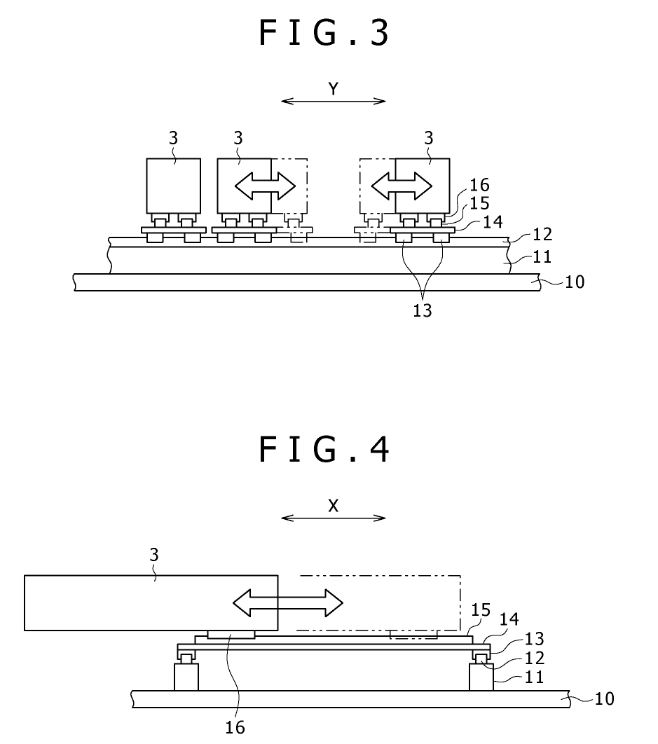

With regard to the Y-direction, as shown in FIG. 3, the two adjacent line-type evaporation sources 3 are moved in such a direction that they are spaced apart from each other, which can increase the distance between the two adjacent line-type evaporation sources 3 compared with that before the movement.

Of the three line-type evaporation sources 3, one disposed on one side of the Y-direction is moved along the rail members 12 to one end (one of movement limit positions) of the Y-direction and the others are moved along the rail members 12 to the other end (the other of the movement limit positions) of the Y-direction. Thus, the greater distance can be ensured between the two adjacent line-type evaporation sources 3.

Further, the three line-type evaporation sources 3 are moved to one end or the other end of the Y-direction to ensure the wide working space for maintenance in the vacuum chamber compared with that before the movement.

On the other hand, with regard to the X-direction, any one of the line-type evaporation sources 3 is moved along the rail members 15 to provide respective open spaces on both sides of the line-type evaporation source 3 that has been moved as shown in FIG. 4. If the standing position of an operator who maintains the deposition apparatus 1 is on the front side of the deposition apparatus 1, the respective wide working spaces can be ensured on both sides of the line-type evaporation source 3 by moving the line-type evaporation source 3 in the X-direction and in a direction of pulling it out toward the front side of the deposition apparatus 1.

By moving all the three line-type evaporation sources 3 to pull them out toward the front side of the apparatus, the broad working space for maintenance can be ensured in the vacuum chamber as compared with that before the movement.

With such a configuration, moving each of the line-type evaporation sources 3 in any of X- and Y-directions can improve maintenance workability. Even if the wide installation interval between the line-type evaporation sources 3 is not set previously, the movement of the line-type evaporation source 3 can ensure a wide space for maintenance. This allows a small floor area of the vacuum chamber to reduce the time necessary for vacuuming. Thus, a deposition apparatus with high productive efficiency can be achieved at a low cost compared with related art. In particular, employing a system of moving the line-type evaporation source 3 in the X-direction for maintenance is more preferable because the interval between the line-type evaporation sources 3 can freely be set without taking account of the Y-directional movement for maintenance.

Incidentally, the embodiment described above is such that the three line-type evaporation sources 3 are supported so as to be movable in the X- and Y-directions. However, the invention is not limited to this configuration. The three line-type evaporation sources 3 may be supported so as to be movable in the X- or Y-direction by selectively using a first slide mechanism composed of a combination of the rail members 12 and the slide members 13 and a second slide mechanism composed of a combination of the rail members 15 and the slide members 16.

In the embodiment described above, the line-type evaporation sources 3 are moved in a horizontal line by installing the movement and support device for moving each of the line-type evaporation sources 3 on the bottom wall 10 of the vacuum chamber. However, the present invention is not limited to this configuration. For example, if the invention is applied to a deposition apparatus in which a conveying device not shown moves a to-be-processed substrate 2 in the Y-direction while vertically supporting it, the line-type evaporation sources 3 may be configured to be moved in a vertical plane by installing the movement and support device on the lateral wall of the vacuum chamber.

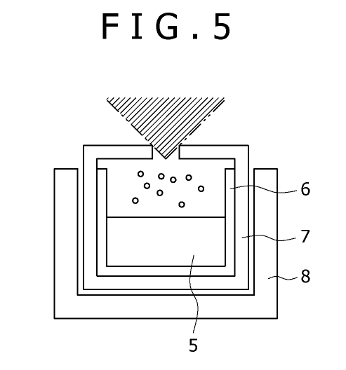

As shown in FIG. 5, the evaporation source generally uses one configured such that a crucible 6 filled with an evaporation material 5 is housed in a nozzle body 7, which is covered from outside by a cooling jacket 8. If the evaporation source configured as above is employed, working efficiency is poor because it is necessary to break down the component parts of the evaporation source in taking the crucible 6 in and out of the nozzle body 7.

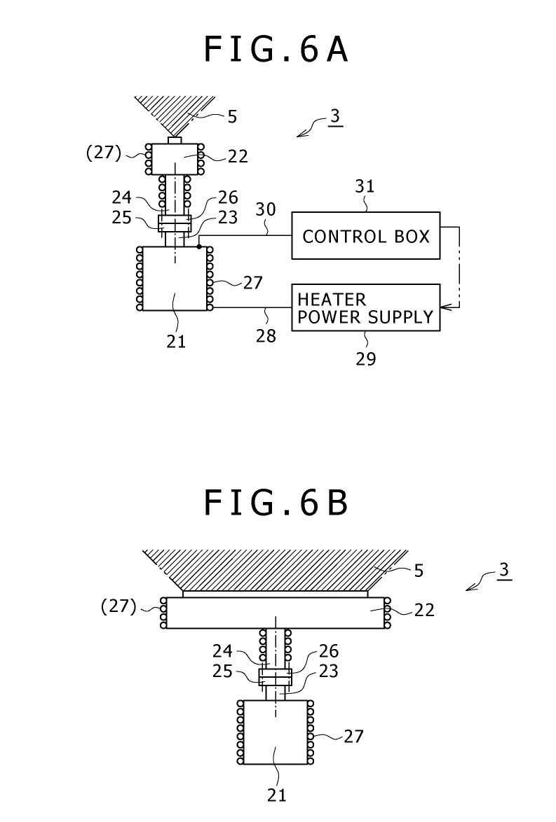

For this reason, the line-type evaporation source 3 described above and used in the embodiment of the present invention is configured as shown in FIGS. 6A and 6B. FIGS. 6A and 6B are schematic views of the line-type evaporation source 3 as viewed from the X- and Y-directions, respectively.

The line-type evaporation source 3 illustrated in the figures is configured so that a crucible 21 and a nozzle 22 can be separated from each other. The crucible 21 is provided with a cylindrical portion 23 and the nozzle 22 is provided with a cylindrical portion 24 which corresponds to the cylindrical portion 23. The cylindrical portion 23 is formed with a flange portion 25 at an upper end and also the cylindrical portion 24 is provided at a lower end with a flange portion 26 which corresponds to the flange portion 25. Both the flange portions 25 and 26 are tightly joined to each other using fastening devices such as bolts and nuts. In this joined state, the respective internal spaces of the cylindrical portions 23 and 24 communicate with each other. Thus, the crucible 21 and the nozzle 22 can be separated from each other at the flange portions 25 and 26.

A heater 27 is wound around the crucible 21 and around the nozzle 22 as well as around the cylindrical portion 24. The heater 27 serves as a heating source for heating the evaporation material contained in the crucible 21. If a heating method of the heater 27 is a resistance heating method using heat conduction for example, the heater 27 is brought into close contact with the crucible 21 and secured thereto by welding or the like. The heater 27 wound around the nozzle 22 and around the cylindrical portion 24 heats the nozzle 22 and the cylindrical portion 24 to prevent the material evaporating from the crucible 21 from cooling and condensing.

The heater 27 is connected to a heater power supply 29 via a line 28. The heater power supply 29 is adapted to supply electric power to the heater 27. A thermocouple 30 is attached to the crucible 21. The thermocouple 30 serves as a temperature detector for detecting the temperature of the crucible 21. The temperature information on the crucible 21 detected by the thermocouple 30 is incorporated into a control box 31. The control box 31 controls electric power supplied from the heater power supply 29 to the heater 27 on the basis of the temperature information of the crucible 21 obtained from the thermocouple 30 so that the temperature of the crucible 21 may become a predetermined temperature.

In general, the evaporation source in the vacuum chamber is often provided with a jacket cooled by water or the like (hereinafter referred to as “the cooling jacket”) in the vicinity of the crucible also shown in FIG. 5. The purposes of this are to improve temperature response for precisely controlling the amount of the material evaporating from the crucible and to increase the temperature drop speed of the crucible after the stop of the heater.

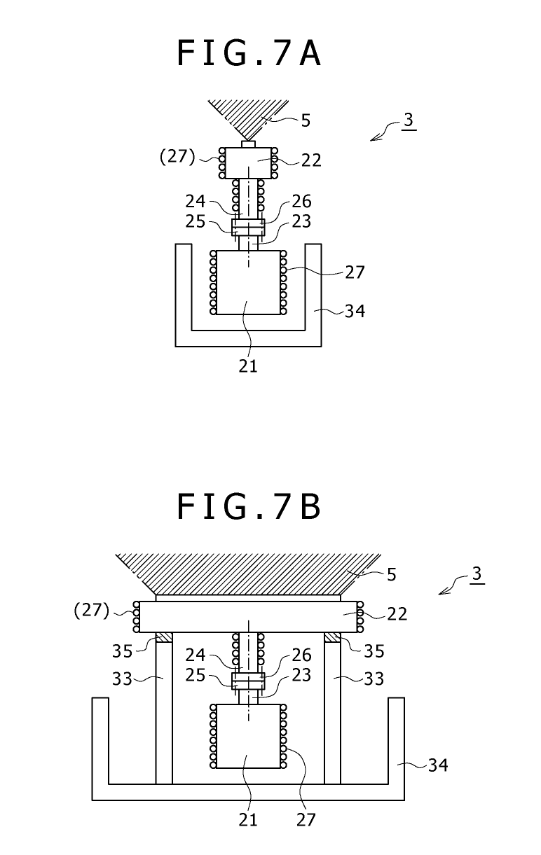

The cooling jacket can be installed for the line-type evaporation source 3 so as to have the following structures. For example, a first installation structure is such that a pair of struts 33 support the nozzle 22 at both near-ends in the longitudinal direction (corresponding to the X-direction) thereof and the cooling jacket 34 surrounds the crucible 21 as illustrated in FIGS. 7A and 7B.

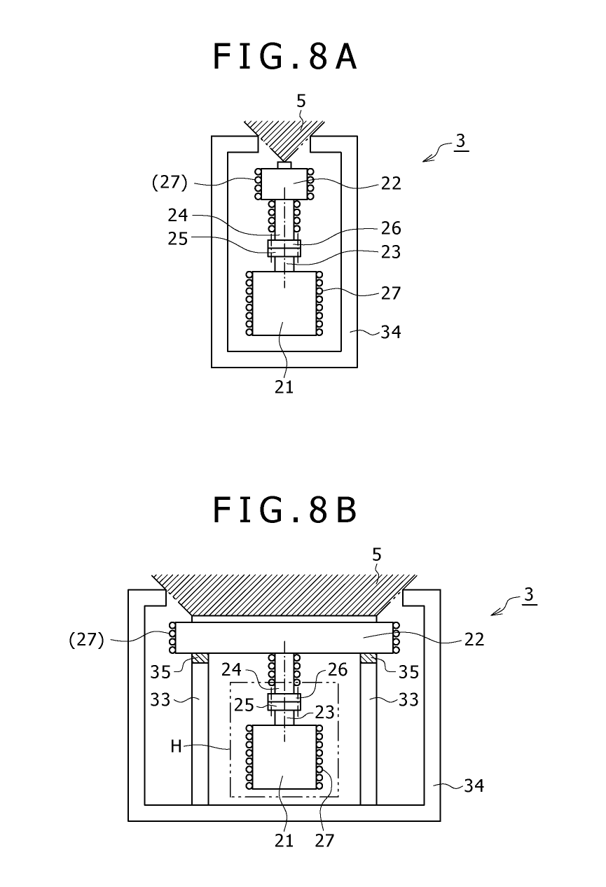

Referring to FIGS. 8A and 8B, a second installation structure is such that a common cooling jacket 34 surrounds both the crucible 21 and the nozzle 22. In addition, the line-type evaporation source 3 is provided in a longitudinal lateral surface with an opening H adapted to take the crucible 21 in and out. This opening H is formed to have a size larger than that of the crucible 21.

The crucible 21 and the nozzle 22 are structured to enable separation from each other. Thus, when the evaporation material is filled in the crucible 21, the crucible 21 can be separated from the nozzle 22 at the flange portions 25 and 26. This facilitates the filling work of the evaporation material. In particular, as in the second installation structure, if the line-type evaporation source 3 is provided with the opening for taking the crucible 21 in and out, it is facilitated to take the crucible 21 in and out of the line-type evaporation source 3 or to replace the crucible 21 when the filling work of the evaporation material is carried out. If the struts 33 are made of metal in the case of adopting any of the installation structures, there is a worry that heat applied to the nozzle 22 by the heater 27 may transmit to the struts 33. It is desirable, therefore, that a heat insulating member 35 made of a material (e.g. ceramic, resin or the like) with low thermal conductivity be interposed between the nozzle 22 and each of the struts 33.

In the first and second installation structures, it may be intended to control the crucible 21 and the nozzle 22 at respective different temperatures by making a portion of the heater 27 wound around the crucible 21 independent as a dedicated heater for the crucible 21 and also by making a portion of the heater 27 wound around the nozzle 22 independent as a dedicated heater for the nozzle 22. In such a case, heat radiating from the portion of the heater 27 wound around the crucible 21 will interfere with heat radiating from the portion of the heater 27 wound around the nozzle 22. This makes it difficult to precisely control the respective temperatures of the crucible 21 and the nozzle 22 at respective optional temperatures.

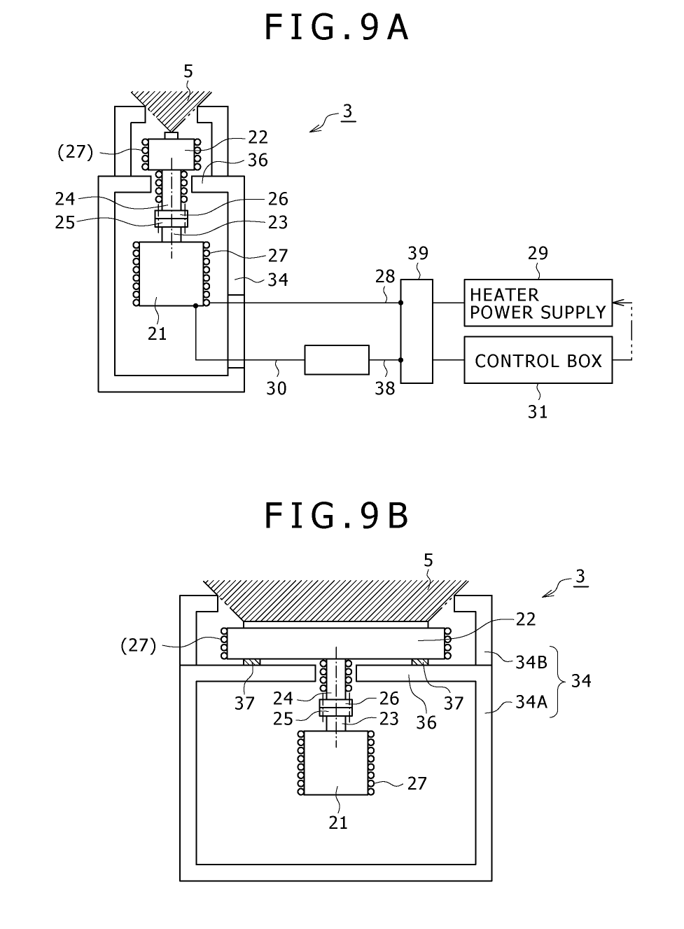

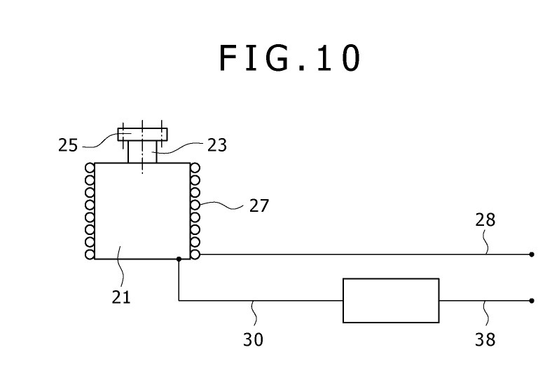

To solve such difficulty, a third installation structure may be adopted in which a partition wall 36 is provided between the crucible 21 and the nozzle 22 to prevent the interference of the radiation heat as illustrated in FIGS. 9A and 9B. The partition wall 36 is cooled by water or the like and is formed as part of the cooling jacket 34. More specifically, the cooling jacket 34 is a structure of combining a lower jacket 34A with an upper jacket 34B. The lower jacket 34A is provided to surround the crucible 21 and the upper jacket 34B is provided to surround the nozzle 22.

The upper jacket 34B is mounted on the lower jacket 34A. A top plate portion of the lower jacket 34A is formed as a partition wall 36. A pair of pedestals 37 placed on the upper surface of the partition wall 36 are used to horizontally support the nozzle 22. The pedestals 37 are made of a material with low thermal conductivity (i.e., heat insulating material) such as, e.g., ceramic or resin. It is desirable that the contact area between the nozzle 22 and the pedestals 37 be as small as possible.

The partition wall 36 is provided with a hole adapted to receive the cylindrical portion 24 of the nozzle 22 passed therethrough. The lower jacket 34A is provided with a wiring port at a portion of the lateral wall thereof. A line 28 connected to the heater 27 and a line 38 connected to the thermocouple 30 are pulled out to the outside of the cooling jacket 34 through the wiring port. Ends of the lines 28 and 38 are connected to a common terminal block 39 provided externally to the cooling jacket 34.

The respective ends of the lines 28 and 38 can each be separated from the terminal block 39. Specifically, the respective ends of the lines 28 and 38 and the terminal portions of the terminal block 39 corresponding to the respective ends of the lines 28 and 38 are provided with connectors having the mail-female relationship. The connectors are taken out of and putted in the corresponding ones to easily separate the lines 28 and 38 from the terminal block 39.

In the case of adopting the third installation structure described above, the partition wall 36 is provided between the crucible 21 and the nozzle 22 to reduce thermal interference therebetween due to their radiation heat. This makes it possible to precisely temperature-control the crucible 21 and the nozzle 22 individually.

The line 28 connected to the heater 27 and the line 38 connected to the thermocouple 30 can be separated from terminal block 39. Thus, a crucible unit which unites the crucible 21, the heater 27, the line 28, the thermocouple 30 and the line 38 is completely separated from the nozzle 22 as shown in FIG. 10. This eliminates the filling work of the evaporation material in a range where the evaporation source can be moved with the lines 28 and 38 remaining connected. There is no worry that the repeated filling work of the evaporation material will damage the lines 28 and 38. The filling work of the evaporation material can be carried out by replacing another crucible unit in which the evaporation material has previously been filled in a crucible 21 without actually filling the evaporation material in the crucible 21 in the vicinity of the evaporation source. This enhances maintenance performance to improve productivity.

If a high-frequency induction heating method or a radiation heating method, for example, is adopted as a heating method of the heater 27, it is not necessary to directly wind the heater 27 around the crucible 21. This makes it possible to configure the crucible unit without the heater 27 and the line 28. Thus, the cost down of the crucible unit can be achieved.

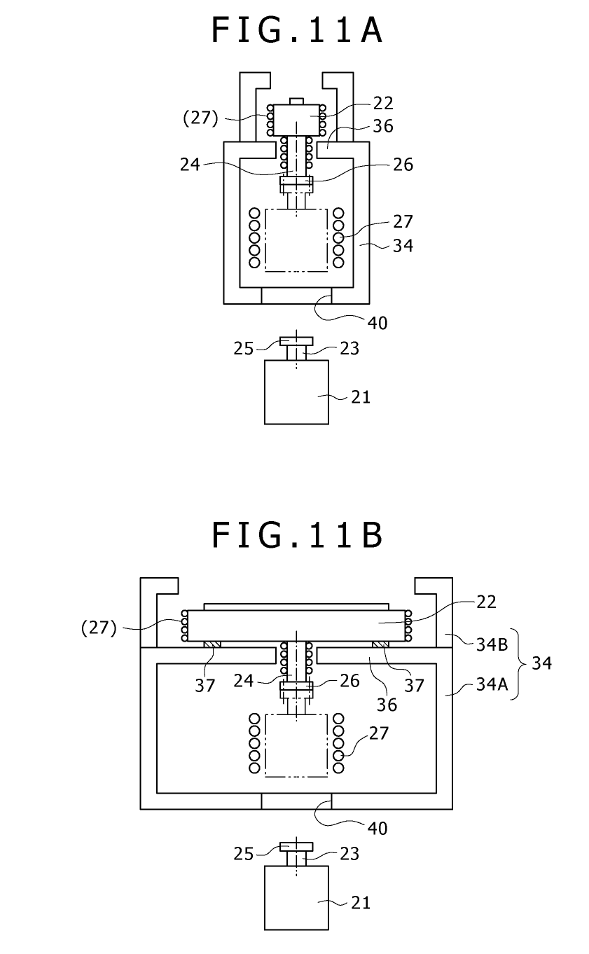

If the high-frequency induction heating method or the radiation heating method mentioned above is adopted, a line-type evaporation source 3 can be configured in which a crucible 21 and a heater 27 for heating the crucible 21 are structurally separated from each other as illustrated in FIGS. 11A and 11B. This makes it possible to take the crucible 21 out of the coil portion of the heater 27 for induction heating or radiation heating or put it therein. If a cooling jacket 34 (a lower jacket 34A) is formed with an opening 40 at the bottom thereof, the crucible 21 can be taken out or put in through the opening 40. Thus, maintenance work for filling the evaporation material can remarkably be simplified to reduce working time.

It should be understood by those skilled in the art that various modifications, combinations, sub-combinations and alternations may occur depending on design requirements and other factors insofar as they are with in the scope of the appended claims or the equivalents thereof.

What is claimed is:

1. A deposition apparatus comprising:
a plurality of line-type evaporation sources provided to be arranged in a predetermined direction; and
movement and support means for supporting the plurality of line-type evaporation sources so as to be individually movable in the arrangement direction and/or longitudinal direction of the evaporation sources.

2. The deposition apparatus according to claim 1, wherein a movement system of the line-type evaporation sources is of an automatic type.

3. The deposition apparatus according to claim 1, wherein each of the line-type evaporation sources includes a crucible adapted to contain an evaporation material and a nozzle adapted to eject the evaporation material evaporating from the crucible, the crucible and the nozzle being able to be separated from each other.

4. The deposition apparatus according to claim 3, wherein the line-type evaporation source is provided in a longitudinal lateral surface with an opening adapted to take the crucible in and out.

5. The deposition apparatus according to claim 3, wherein a partition wall is provided between the crucible and the nozzle.

6. The deposition apparatus according to claim 3, wherein the line-type evaporation source includes a heating source for heating the evaporation material contained in the crucible and temperature detecting means for detecting the temperature of the crucible and is configured such that a crucible unit including the crucible, the nozzle, the heating source and the temperature detecting means can be separated from the nozzle.
